(19) United States
(12) Patent Application Publication
(10) Pub. No.: US 2026/0193783 A1
(43) Pub. Date: Jul. 9, 2026

(54) ALUMINUM HYDRIDE PRECURSOR FOR ALUMINUM METAL ALD

(71) Applicant: Applied Materials, Inc., Santa Clara, CA (US)

(72) Inventors: Jayeeta SEN, Bangalore (IN); Gargi BHATT, Bangalore (IN); Tanu SHARMA, Bangalore (IN); Gopi Chandran RAMACHANDRAN, Mumbai (IN); Geetika BAJAJ, Cupertino, CA (US); Seshadri GANGUIL, Santa Clara, CA (US); Tuerxun AILIHUMAER, Santa Clara, CA (US); Srinivas GANDIKOTA, Santa Clara, CA (US)

(21) Appl. No.: 19/175,165

(22) Filed: Apr. 10, 2025

(30) Foreign Application Priority Data
Jan. 8, 2025 (IN) 202541001711

(51) Int. Cl. C23C 16/455; C23C 16/12

(52) U.S. Cl. CPC C23C 16/45553; C23C 16/12

(57) ABSTRACT

Embodiments of the present disclosure relate to compositions and methods for forming metal films. In at least some embodiment, a composition of matter includes a metal-hydride precursor represented by a general formula (I), a general formula (II), or oligomers thereof, where M is a trivalent metal and each of R¹, R², R³, R^{3′}, R4, and R^{4′} independently include a C₁-C₂₀ unsubstituted alkyl group, a C₁-C₂₀ substituted alkyl group, a C₁-C₂₀ unsubstituted alkenyl group, a C₁-C₂₀ substituted alkenyl group, a C₁-C₂₀ unsubstituted alkynyl group, a C₁-C₂₀ substituted alkynyl group, a trialkylsilyl group, a substituted aromatic group, an unsubstituted aromatic group, a non-metal atom, a non-metal group, or combinations thereof.

### CROSS-REFERENCE TO RELATED APPLICATIONS

This application claims benefit of Indian Provisional patent application Ser. No. 202541001711, filed Jan. 8, 2025, which is herein incorporated by reference in its entirety.

### FIELD

Embodiments disclosed herein generally relate to the fabrication of semiconductor and other electronic devices, and particularly to compositions and methods for forming a metal film by an atomic layer deposition (or other suitable deposition) process.

### BACKGROUND

Thin-film deposition is utilized in semiconductor device fabrication to create and deposit thin film coatings onto a substrate material. For example, thin-film deposition may be used in the manufacture of electronics like integrated circuits, as well as other products. Thin-film deposition may involve using a chemical vapor deposition (CVD) process or an atomic layer deposition (ALD) process. The deposition of aluminum metal films is particularly prevalent in semiconductor device fabrication.

### SUMMARY

Embodiments disclosed herein generally relate to the fabrication of semiconductor and other electronic devices. More particularly, some embodiments disclosed herein relate to compositions and methods for forming high purity metal films via a thermal ALD process (or other suitable deposition process).

In at least some embodiments, a composition of matter is provided. The composition of matter includes a metal-hydride precursor represented by a general formula (I)

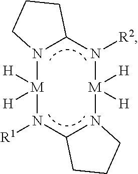

a general formula (II)

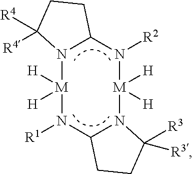

or oligomers thereof where M is a trivalent metal and each of R¹, R², R³, R^{3′}, R⁴, and R^{4′} independently include a C₁-C₂₀ unsubstituted alkyl group, a C₁-C₂₀ substituted alkyl group, a C₁-C₂₀ unsubstituted alkenyl group, a C₁-C₂₀ substituted alkenyl group, a C₁-C₂₀ unsubstituted alkynyl group, a C₁-C₂₀ substituted alkynyl group, a trialkylsilyl group, a substituted aromatic group, an unsubstituted aromatic group, a non-metal atom, a non-metal group, or combinations thereof.

In at least some embodiments, a method for forming a film is provided and includes sequentially exposing a surface to a first precursor and a second precursor to form a film including a metal and a metal alloy. The first precursor comprises a metal-hydride precursor represented by a general formula (I)

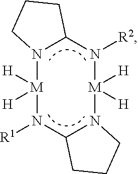

a general formula (II)

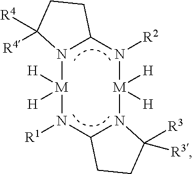

or oligomers thereof, where M is a trivalent metal and each of R¹, R², R³, R^{3′}, R⁴, and R^{4′} independently include a C₁-C₂₀ unsubstituted alkyl group, a C₁-C₂₀ substituted alkyl group, a C₁-C₂₀ unsubstituted alkenyl group, a C₁-C₂₀ substituted alkenyl group, a C₁-C₂₀ unsubstituted alkynyl group, a C₁-C₂₀ substituted alkynyl group, a trialkylsilyl group, a substituted aromatic group, an unsubstituted aromatic group, a non-metal atom, a non-metal group, or combinations thereof.

In at least some embodiments, a method for forming a film is provided and includes sequentially exposing a surface to a first precursor and a second precursor to form a film including a metal and a metal alloy. The first precursor includes an alane precursor represented by a formula (III)

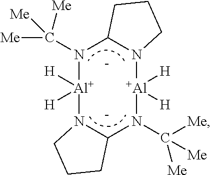

and the second precursor including a metal halide.

### BRIEF DESCRIPTION OF THE DRAWINGS

Embodiments disclosed herein, which are discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 is a schematic block diagram of a deposition process, according to some embodiments.

FIG. 2 is a schematic block diagram of a metal film deposition process, according to some embodiments.

### DETAILED DESCRIPTION

Thin-film deposition, such as aluminum (Al) metal film deposition, is particularly prevalent in semiconductor device fabrication. Conventional methods for depositing Al metal films include plasma-enhanced atomic layer deposition (PEALD) using trimethylaluminium (AlMe₃) and hydrogen plasma. However, the energetic plasma species generated during a PEALD process can damage the substrate and hinder step coverage due to rapid hydrogen recombination. The Al precursors currently available for thermal atomic layer deposition (ALD) processes are thermally instable and result in the incorporation of impurities in deposited Al metal films. Accordingly, there is a need in the art for improved Al precursors and deposition methods to form metal films.

Accordingly, embodiments disclosed herein generally relate to the fabrication of semiconductor and other electronic devices. More particularly, embodiments disclosed herein provide compositions and methods for forming metal films. It has been discovered that high purity metal films may be deposited using the metal-hydride precursors and methods disclosed herein. In at least some embodiments, the disclosed metal-hydride precursors are thermally stable up to about 600 Kelvin (K) and act as metal-hydride reducing agents. In at least some embodiments, Al metal films produced using the methods disclosed herein have a purity greater than about 80% and have an atomic % of chlorine (Cl), carbon (C), and/or nitrogen (N) of less than 20%. In at least some embodiments, the methods disclosed herein include exposing (such as sequentially exposing or simultaneously exposing) a surface (e.g., a surface of a substrate) to a first precursor and a second precursor to form a film comprising a metal and a metal alloy.

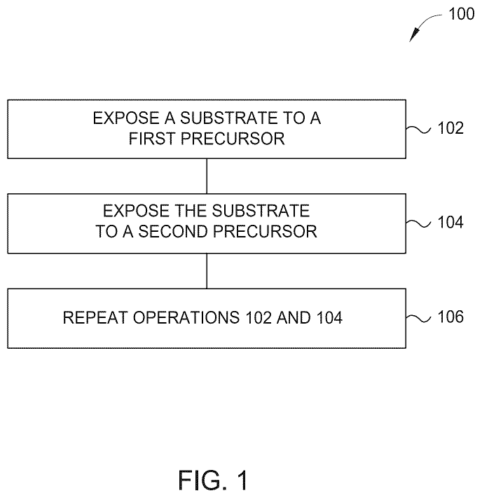

FIG. 1 is a schematic block diagram of a deposition process, according to some embodiments described herein. In at least some embodiments, the method 100 may be an ALD process, a chemical vapor deposition (CVD) process, or a hybrid ALD-CVD process. In at least some embodiments, the method 100 is a thermal ALD process. In at least some embodiments, the method 100 generally includes sequentially exposing a surface of a substrate to a first precursor and a second precursor to form a film comprising a metal and/or a metal alloy. The method 100 may be carried out in any suitable process chamber. Examples of suitable process chambers include a Centura™ CVD W deposition chamber and an Olympia® ALD deposition chamber available from Applied Materials, Inc., located in Santa Clara, CA.

At operation 102, a substrate is exposed to a first precursor. In at least some embodiments, the first precursor is a metal-hydride precursor that acts as a metal-hydride reducing agent. The metal-hydride precursor may be thermally stable up to about 600K, such as about 200K to about 600K, about 300K to about 600K, or about 400K to about 600K. The high thermal stability of the first precursor allows the first precursor to be used in thermal ALD processes without breaking down or incorporating impurities into the deposited film.

In at least some embodiments, the metal-hydride precursor is a metal (III) di(iminopyrrolidinate) compound. In at least some embodiments, the first precursor includes a metal-hydride precursor represented by the general formula (I):

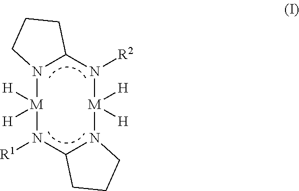

where M of formula (I) may be any trivalent metal and each of R¹ and R² may independently be a C₁-C₂₀ unsubstituted alkyl group, a C₁-C₂₀ substituted alkyl group, a C₁-C₂₀ unsubstituted alkenyl group, a C₁-C₂₀ substituted alkenyl group, a C₁-C₂₀ unsubstituted alkynyl group, a C₁-C₂₀ substituted alkynyl group, a trialkylsilyl group, a substituted aromatic group, an unsubstituted aromatic group, other non-metal atoms, or other non-metal groups. In at least some embodiments, R¹ and R² may independently be or include methyl (Me), methoxy (OMe), ethyl (Et), ethoxy (OEt), isopropyl (iPr), isoproproxy (OiPr), or tert-butyl (tBu). In at least some embodiments, M of formula (I) may be Al, Scandium (Sc), Gallium (Ga), Indium (In), Cobalt (Co), Iron (Fe), Vanadium (V), Manganese (Mn), or any lanthanide metal. In at least some embodiments, M of formula (I) is Al. In at least some embodiments, R₁ and R₂ may independently be a C₁-C₂₀ unsubstituted alkyl group, a C₁-C₂₀ substituted alkyl group, a substituted aromatic group, or an unsubstituted aromatic group, where the C₁-C₂₀ substituted alkyl group and the substituted aromatic group have a non-metal substitution.

In at least some embodiments, the first precursor includes a metal-hydride precursor represented by the general formula (II):

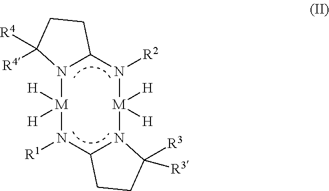

where M of formula (II) may be any trivalent metal and each of R¹, R², R³, R^{3′}, R⁴, and R^{4′} may independently be a C₁-C₂₀ unsubstituted alkyl group, a C₁-C₂₀ substituted alkyl group, a C₁-C₂₀ unsubstituted alkenyl group, a C₁-C₂₀ substituted alkenyl group, a C₁-C₂₀ unsubstituted alkynyl group, a C₁-C₂₀ substituted alkynyl group, a trialkylsilyl group, a substituted aromatic group, an unsubstituted aromatic group, other non-metal atoms, or other non-metal groups. In at least some embodiments, R¹, R², R³, R^{3′}, R⁴, and R^{4′} may independently be or include methyl (Me), methoxy (OMe), ethyl (Et), ethoxy (OEt), isopropyl (iPr), isoproproxy (OiPr), or tert-butyl (tBu). In at least some embodiments, M of formula (II) may be Al, Sc, Ga, In, Co, Fe, V, Mn, or any lanthanide metal. In at least some embodiments, M of formula (II) is Al. In at least some embodiments, R¹, R², R³, R^{3′}, R⁴, and R^{4′} may independently be a C₁-C₂₀ unsubstituted alkyl group, a C₁-C₂₀ substituted alkyl group, a substituted aromatic group, or an unsubstituted aromatic group, where the C₁-C₂₀ substituted alkyl group and the substituted aromatic group have a non-metal substitution.

In at least some embodiments, the first precursor is an alane precursor, such as aluminum (III) di(tert-butyl iminopyrrolidinate) represented by formula 3:

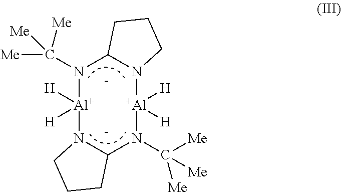

In such embodiments, the first precursor may be used to deposit an Al-metal film.

In at least some embodiments, the metal-hydride precursors represented by formula (I) and (II) may be formed (e.g., synthesized) by reacting substituted or unsubstituted iminopyrrolidine ligands with AlH₃N(CH₃)₃ or by reacting substituted or unsubstituted iminopyrrolidine ligands with AlH₃(OEt₂)ₓ. In at least some embodiments, the iminopyrrolidine ligands may have a propyl, iso-propyl, butyl, iso-butyl, sec-butyl, and/or tert-butyl substitution.

In at least some embodiments, the formation energy for the formation of the metal-hydride precursors represented by formula (I) and (II) is negative. For example, in at least some embodiments the formation energy of the metal-hydride precursors may be about −200 kilojoules per mole (kJ/mol) to about −500 kJ/mol, such as about −200 kJ/mol to about −400 kJ/mol, about −250 kJ/mol to about −350 kJ/mol, or about −300 kJ/mol to about −400 kJ/mol. In at least some embodiments, Density Functional Theory (DFT) calculations were performed to determine the formation energies and the thermal stability of the metal-hydride precursor. The formation energies were calculated at about 300K to about 600K and the formation energies were found to be negative, thus the formation of metal-hydride precursors is highly favorable.

In at least some embodiments, the first precursor has a percent purity of about 97% or greater, such as about 98% or greater, or about 99% or greater. In at least some embodiments, the first precursor may contain less than 5 parts per million (ppm) of a metal other than Al, such as about 0 ppm to about 4.9 ppm, about 1 ppm to about 4 ppm, or about 2 ppm to about 4 ppm. The first precursor may contain small amounts of other impurities, such as iminopyrrolidine, phosphorous, aluminum metal, and/or amines.

In at least some embodiments, the first precursor may be introduced into a processing volume while maintaining a pressure of about 3 Torr to about 50 Torr and a temperature of about 500° C. or less. In at least some embodiments, the processing volume may be maintained at a pressure of about 1 Torr to about 50 Torr, such as about 1 Torr to about 40 Torr, about 1 Torr to about 30 Torr, about 1 Torr to about 20 Torr, about 1 Torr to about 10 Torr, about 3 Torr to about 10 Torr, or about 3 Torr to about 20 Torr. In at least some embodiments, the processing volume may be maintained at a temperature of about 50° C. to about 500° C., such as about 50° C. to about 450° C., about 50° C. to about 400° C., about 50° C. to about 350° C., about 100° C. to about 500° C., about 100° C. to about 400° C., or about 100° C. to about 300° C.

In at least some embodiments, the substrate may be exposed to the first precursor for about 1 second (s) to about 5 minutes (min), such as about 1 s to about 4 min, about 1 s to about 3 min, about 1 s to about 2 min, or about 1 s to about 1 min. In at least some embodiments, a carrier gas, such as argon (Ar), helium (He), nitrogen (N₂), xenon (Xe), or combinations thereof may be supplied with the first precursor and/or following providing the first precursor. The carrier gas may be introduced into the processing volume at a flow rate of about 20 standard cubic centimeters per minute (sccm) to about 1,000 sccm, such as about 30 sccm to about 800 sccm, about 50 sccm to about 600 sccm, or about 40 sccm to about 500 sccm.

At operation 104, the substrate is exposed to a second precursor. In at least some embodiments, the second precursor includes a metal halide. In at least some embodiments, the metal of the metal halide may include a metal having a +1 to a +5 oxidation state. In at least some embodiments, the metal of the metal halide may include Al, Titanium (Ti), Tantalum (Ta), Zirconium (Zr), Hafnium (Hf), Niobium (Nb), Tungsten (W), Silicon (Si), Germanium (Ge), Phosphorus (P), Magnesium (Mg), Zinc (Zn), any lanthanide metal, any other transition metal, or combinations thereof. The halide of the metal halide may include Cl, bromine (Br), iodide (I), or combinations thereof. In at least some embodiments, the second precursor is aluminum chloride (AlCl₃).

In at least some embodiments, the second precursor includes a metal amide represented by formula (IV):

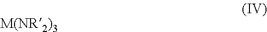

where M of formula (IV) may be any trivalent metal and R′ may be a C₁-C₂₀ unsubstituted alkyl group, a C₁-C₂₀ substituted alkyl group, a C₁-C₂₀ unsubstituted alkenyl group, a C₁-C₂₀ substituted alkenyl group, a C₁-C₂₀ unsubstituted alkynyl group, a C₁-C₂₀ substituted alkynyl group, a keto group, or an aldehyde group.

In at least some embodiments, the second precursor may include trimethyl aluminum, triethyl aluminum, or combinations thereof.

In at least some embodiments, the second precursor may be introduced into a processing volume while maintaining a pressure of about 3 Torr to about 50 Torr and a temperature of about 500° C. or less. In at least some embodiments, the processing volume may be maintained at a pressure of about 1 Torr to about 50 Torr, such as about 1 Torr to about 40 Torr, about 1 Torr to about 30 Torr, about 1 Torr to about 20 Torr, about 1 Torr to about 10 Torr, about 3 Torr to about 10 Torr, or about 3 Torr to about 20 Torr. In at least some embodiments, the processing volume may be maintained at a temperature of about 50° C. to about 500° C., such as about 50° C. to about 450° C., about 50° C. to about 400° C., about 50° C. to about 350° C., about 100° C. to about 500° C., about 100° C. to about 400° C., or about 100° C. to about 300° C.

In at least some embodiments, the substrate may be exposed to the second precursor for about 1 second (s) to about 5 minutes (min), such as about 1 s to about 4 min, about 1 s to about 3 min, about 1 s to about 2 min, or about 1 s to about 1 min. In at least some embodiments, a carrier gas, such as argon (Ar), helium (He), nitrogen (N₂), xenon (Xe), or combinations thereof may be supplied with the second precursor and/or following providing the second precursor. The carrier gas may be introduced into the processing volume at a flow rate of about 20 sccm to about 1,000 sccm, such as about 30 sccm to about 800 sccm, about 50 sccm to about 600 sccm, or about 40 sccm to about 500 sccm.

Without being bound by this or any particular theory, it is believed that in at least some embodiments, the metal-hydride first precursor may react with the metal halide second precursor to form a metal-hydride. It is further believed that the formed metal-hydride decomposes into the pure metal (that is deposited on the substrate) and hydrogen gas (H₂). The reaction may proceed through two intermediates that remain as byproducts of the reaction. For example, in at least some embodiments, the alane precursor represented by formula (III) may be reacted with aluminum chloride (AlCl₃) to form Al metal and H₂. The reaction may proceed through a first metal-hydride monochloride intermediate represented by formula (V) and a second metal-dichloride intermediate represented by formula (VI):

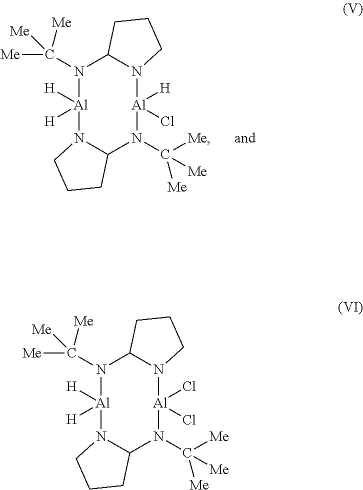

In at least some embodiments, a reaction mechanism proceeding through the first intermediate represented by formula (V) and the second intermediate represented by formula (VI) has a low activation barrier, allowing Al metal to be deposited at low temperatures. For example, in at least some embodiments, computed Potential Energy Surface (PES) of the first intermediate represented by formula (V) and the second intermediate represented by formula (VI) are about −20 Joules (J) to about −50 J and the PES of the transition structures are about 2 J to about 15 J.

At operation 106, operations 102 and 104 are repeated to form a metal film including a pure metal and/or metal alloys. In at least some embodiments, the metal film has a purity greater than about 80%, such as greater than about 85%, greater than about 90%, or greater than about 95%. In at least some embodiments, the metal film may have an atomic % of Cl, C, and/or N of less than 20%, such as less than about 10%, less than about 5%, about 0% to about 19%, about 0% to about 15%, about 0% to about 10%, about 0% to about 4.9%, about 1% to about 4%, or about 2% to about 3%.

In at least some embodiments, the metal film includes Al, Ti, Ta, Zr, Hf, W, Si, Ge, P, any lanthanide metal, alloys thereof, or combinations thereof. In at least some embodiments, the metal film includes a pure metal in zero oxidation state. In at least some embodiments, the metal film is a high purity Al metal film. In at least some embodiments, the metal film is an Al metal film including Al alloys such as, AlTi, AlMg, AlCu, AlMn, AlSi, AlNi, AlZn, or combinations thereof. In at least some embodiments the metal films disclosed herein may at least partially form or define one or more films in a semiconductor device or a quantum device.

In at least some embodiments, operations 102 and 104 are performed simultaneously (or at least partially overlapped), such that the surface is exposed to the first precursor and the second precursor at the same time. In such embodiments, the method 100 may be a CVD process.

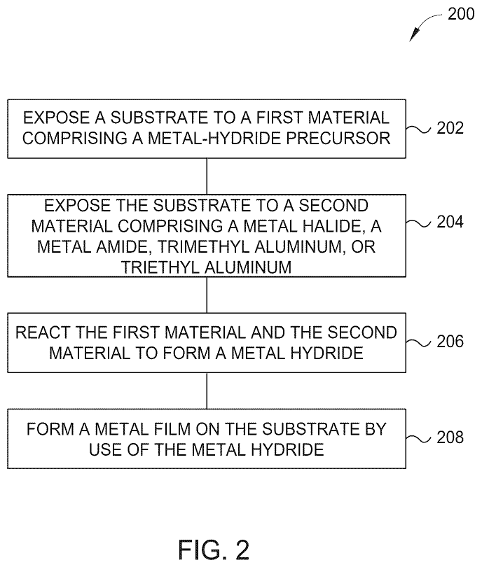

FIG. 2 is a schematic block diagram of a metal film deposition process, according to some embodiments. In at least some embodiments, the method 200 may be an ALD process, a CVD process, or a hybrid ALD-CVD process. In at least some embodiments, the method 200 is a thermal ALD process. In at least some embodiments, the method 200 generally includes exposing a substrate to a first material, exposing the substrate to a second material, reacting the first material and the second material to form a metal-hydride, and forming a metal film on the substrate by use of the metal-hydride.

At operation 202, a substrate is exposed to a first material comprising a metal-hydride precursor. In at least some embodiments, the metal-hydride precursor may be a metal-hydride precursor represented by the general formula (I) or the general formula (II) as described in operation 102 of method 100. In at least some embodiments, the first material may be introduced into a processing volume while maintaining a pressure of about 3 Torr to about 50 Torr and a temperature of about 500° C. or less. The substrate may be exposed to the first precursor for about 1 s to about 5 min. In at least some embodiments, a carrier gas, such as Ar, He, N₂, Xe, or combinations thereof may be supplied with the first material and/or following providing the first material. The carrier gas may be introduced into the processing volume at a flow rate of about 20 sccm to about 1,000 sccm. In at least some embodiments, operation 202 may be carried out using the same process conditions described in operation 102 of method 100.

At operation 204, a substrate is exposed to a second material comprising a metal halide, a metal amide, trimethyl aluminum, or triethyl aluminum. In at least some embodiments, the metal halide is a metal halide as described in operation 104 of method 100. In at least some embodiments, the metal amide is a metal amide represented by formula (IV) as described in operation 104 of method 100. In at least some embodiments, the second material may be introduced into a processing volume while maintaining a pressure of about 3 Torr to about 50 Torr and a temperature of about 500° C. or less. The substrate may be exposed to the second material for about 1 s to about 5 min. In at least some embodiments, a carrier gas, such as Ar, He, N₂, Xe, or combinations thereof may be supplied with the second material and/or following providing the second material. The carrier gas may be introduced into the processing volume at a flow rate of about 20 sccm to about 1,000 sccm. In at least some embodiments, operation 204 may be carried out using the same process conditions described in operation 104 of method 100.

At operation 206, the first material and the second material are reacted to form a metal-hydride. At operation 208, a metal film is formed on the substrate by use of the resultant metal-hydride. In at least some embodiments, metal film is formed by the decomposition of the metal-hydride. The metal-hydride decomposes into the pure metal (that is deposited on the substrate) and H₂.

Over all, the embodiments disclosed herein include compositions and methods for forming high purity metal films. The methods generally include exposing (such as sequentially exposing or simultaneously exposing) a surface (e.g., a surface of a substrate) to a first precursor and a second precursor to form a film comprising a metal and a metal alloy. In at least some embodiments, the methods disclosed herein produce metal films have a purity greater than about 80% and have an atomic % of Cl, C, and/or N of less than 20%. In at least some embodiments, the disclosed metal-hydride precursors are thermally stable up to about 600K and act as metal-hydride reducing agents. The high thermal stability of the precursors may allow the precursors to be used in thermal ALD processes without breaking down or incorporating impurities into the deposited film.

While the foregoing is directed to embodiments of the present disclosure, other and further embodiments of the disclosure may be devised without departing from the basic scope thereof. The present disclosure also contemplates that one or more aspects of the embodiments described herein may be substituted in for one or more of the other aspects described. The scope of the disclosure is determined by the claims that follow.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges appear in one or more claims below.

1. A composition of matter comprising:
a metal-hydride precursor represented by a general formula (I) 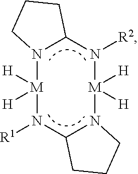
a general formula (II) 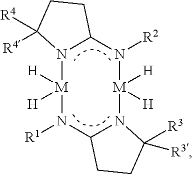
or oligomers thereof, wherein M is a trivalent metal and each of R¹, R², R³, R^{3′}, R⁴, and R^{4′} independently comprise a C₁-C₂₀ unsubstituted alkyl group, a C₁-C₂₀ substituted alkyl group, a C₁-C₂₀ unsubstituted alkenyl group, a C₁-C₂₀ substituted alkenyl group, a C₁-C₂₀ unsubstituted alkynyl group, a C₁-C₂₀ substituted alkynyl group, a trialkylsilyl group, a substituted aromatic group, an unsubstituted aromatic group, a non-metal atom, a non-metal group, or combinations thereof.

2. The composition of matter of claim 1, wherein the trivalent metal comprises Al.

3. The composition of matter of claim 2, wherein the metal-hydride precursor is aluminum (III) di(tert-butyl iminopyrrolidinate) represented by formula III

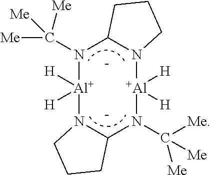

4. The composition of matter of claim 1, wherein the trivalent metal comprises Sc, Ga, In, Co, Fe, V, Mn, a lanthanide metal, or combinations thereof.

5. The composition of matter of claim 1, wherein each of R¹, R², R³, R^{3′}, R⁴, and R^{4′} independently comprise a C₁-C₂₀ unsubstituted alkyl group, an unsubstituted aromatic group, a C₁-C₂₀ substituted alkyl group having a non-metal substitution, a substituted aromatic group having a non-metal substitution, or combinations thereof.

6. The composition of matter of claim 1, wherein the composition of matter has a purity of greater than about 97%.

7. The composition of matter of claim 1, wherein the metal-hydride precursor is thermally stable at about 600 K or less.

8. A method for forming a film, the method comprising:
sequentially exposing a surface to a first precursor and a second precursor to form a film comprising a metal and a metal alloy,
wherein the first precursor comprises a metal-hydride precursor represented by a general formula (I) 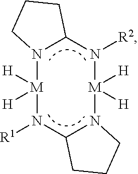
a general formula (II) 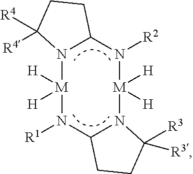
or oligomers thereof, and wherein M is a trivalent metal and each of R¹, R², R³, R^{3′}, R⁴, and R^{4′} independently comprise a C₁-C₂₀ unsubstituted alkyl group, a C₁-C₂₀ substituted alkyl group, a C₁-C₂₀ unsubstituted alkenyl group, a C₁-C₂₀ substituted alkenyl group, a C₁-C₂₀ unsubstituted alkynyl group, a C₁-C₂₀ substituted alkynyl group, a trialkylsilyl group, a substituted aromatic group, an unsubstituted aromatic group, a non-metal atom, a non-metal group, or combinations thereof.

9. The method of claim 8, wherein the film comprises less than about 20 atomic % of N, Cl, and C.

10. The method of claim 8, wherein the second precursor comprises a metal halide.

11. The method of claim 10, wherein the metal halide comprises a metal having an oxidation state of +1 to +5, Al, Ti, Ta, Zr, Hf, Nb, W, Si, Ge, P, Mg, Zn, a lanthanide metal, other transition metal, or combinations thereof.

12. The method of claim 10, wherein the metal halide comprises chlorine, bromine, or iodide.

13. The method of claim 10, wherein the film comprises a metal in a zero oxidation state.

14. The method of claim 10, wherein the metal halide is AlCl₃.

15. The method of claim 8, wherein the second precursor comprises a metal amide having a formula (M(NR′₂)₃), wherein M comprises a trivalent metal and R′ comprises a C₁-C₂₀ unsubstituted alkyl group, a C₁-C₂₀ substituted alkyl group, a C₁-C₂₀ unsubstituted alkenyl group, a C₁-C₂₀ substituted alkenyl group, a C₁-C₂₀ unsubstituted alkynyl group, a C₁-C₂₀ substituted alkynyl group, a keto group, an aldehyde group, or combinations thereof.

16. The method of claim 8, wherein the second precursor comprises trimethyl aluminum, triethyl aluminum, or combinations thereof.

17. The method of claim 8, further comprising maintaining a temperature of about 500° C. or less while exposing the surface to the first precursor and the second precursor.

18. The method of claim 8, wherein the film is a film in a semiconductor device or a quantum device.

19. A method for forming a film, comprising:
sequentially exposing a surface to a first precursor and a second precursor to form a film comprising a metal and a metal alloy,
wherein the first precursor comprises an alane precursor represented by a formula (III) 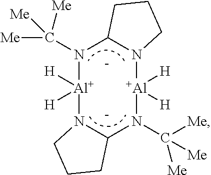
and
wherein the second precursor comprises a metal halide.

20. The method of claim 19, wherein the film comprises less than about 20 atomic % of N, Cl, and C.
